(19) United States
(12) Patent Application Publication
(10) Pub. No.: US 2002/0127822 A1
(43) Pub. Date: Sep. 12, 2002

(54) Semiconductor device and method of manufacturing the same

(76) Inventors: Katsumichi Ueyanagi, Nagano (JP); Mitsuo Sasaki, Nagano (JP); Toshiaki Sakai, Nagano (JP)

Correspondence Address: ROSSI & ASSOCIATES, P.O. Box 826, Ashburn, VA, 20146-0826, US

(21) Appl. No.: 10/083,712

(22) Filed: Feb. 25, 2002

(30) Foreign Application Priority Data
Feb. 23, 2001 (JP) 2001-048654

(51) Int. Cl. H01L 21/30; H01L 21/46; H01L 27/01

(52) U.S. Cl. 438/459; 257/347

(57) ABSTRACT

A high-concentration impurity region is formed on all or a part of a surface of an Si forming the third layer, an oxide film (SiO₂) forming the second layer is formed on the entire surface of the third layer, the third layer and an Si substrate forming the first layer are bonded together, and the Si forming the third layer is mirror-polished to manufacture an SOI wafer. A resist is then patterned on the SOI wafer, grooves and holes for specifying the contour of the structure are formed in the Si forming the third layer, and the oxide film SiO2 forming the second layer opposed to the formed detecting structure is removed. At the same time, an uneveness of about 0.01 to 0.5 μm is formed on the surface of the third layer, on which the high-concentration impurity region is formed. The unevenness reduces the contact area between the third layer and the first layer, and reduces the adhering power of the third layer toward the first layer, which is generated by a surface tension 300 of liquid, to surely prevent a sticking phenomenon.

### BACKGROUND

FIGS. 7(a)-7(g) show an example of a conventional process of manufacturing a semiconductor device. FIGS. 7(a)-7(e) refer to the sectional views of the semiconductor device during its manufacturing process, whereas FIGS. 7(f)-7(g) respectively refer to the top and enlarged views of the manufactured semiconductor device.

Referring to FIG. 7(a), an insulating layer 11 formed of BPSG (boron phosphorous silica glass) or PSG (phosphorous silica glass) is formed on the upper surface of an Si (silicon) substrate 10, and a polysilicon 12 serving as a movable electrode and a fixed electrode is formed on the insulating layer 11. An SOI (silicon on insulator) wafer is formed by bonding together the Si substrate 10, the insulating layer 11 formed of oxide film, and an Si active layer 12. Referring to FIG. 7(b), a detecting structure 13 is formed of a polysilicon or an active layer Si by patterning and etching a resist. Thereafter, referring to FIG. 7(c), the insulating layer 11 formed of BPSG, PSG, oxide film, or the like is etched as a scarifying layer using an etching solution 20, such as an aqueous solution including BHF. Thereafter, the resist is cleaned with cleaning liquid, such as pure water and IPA (isopropyl alcohol), and is then dried, referring to FIG. 7(d). The surface tension 21 generated by the cleaning liquid during the cleaning step is formed in a gap between the polysilicon structure 13 and the Si substrate 10, referring to FIG. 7(e). This causes the polysilicon structure 13 with a low rigidity to be absorbed and secured or adhered to the Si substrate 10 (this will hereinafter referred to as “sticking phenomenon”), referring to FIG. 7(e).

To address this problem, Japanese Laid-Open Patent Publication No. 7-505743 has proposed an invention as shown in FIGS. 8(a)-(h). FIG. 8(a) illustrates an insulating layer 11 formed of BGSG, PSG, or the like formed on the upper surface of an Si substrate 10, and a polysilicon layer 12 serving as movable and fixed electrodes is formed on the insulating layer 11. As in the former process (FIG. 7(b)), an SOI wafer is formed by bonding together the Si substrate 10, the insulating layer 11 formed of oxide film, and an Si active layer. Thereafter, a detecting structure 13 of a polysilicon or an active layer Si is formed by patterning and etching a resist, referring to FIG. 8(b). Thereafter, the first sacrifice layer etching process is carried out while preventing the detecting structure 13 from becoming completely free, referring to FIG. 8(c). Thereafter, referring to FIG. 8(d), a photosensitive polymer 30 is patterned while supporting the detecting structure 13.

Referring to FIG. 8(e), the detecting structure 13 is dried by etching the second scarifying layer. Since the rigidity of the photosensitive polymer 30 supports the detecting structure, the sticking phenomenon does not occur. Thereafter, referring to FIG. 8(f), the photosensitive polymer 30 is removed by a drying step, such as ashing to complete the detecting structure 13 in a free state. See FIGS. 8(g) and 8(h).

However, in the conventional process shown in FIGS. 8(a)-8(h), after the first scarifying layer is etched, it is difficult to accurately pattern the photosensitive polymer 30 such that it forms an unevenness in height of several μm. It is also difficult to cause the photosensitive polymer 30 to penetrate a wafer to the bottom thereof from which the first scarifying layer is etched. Moreover, it is also difficult to completely remove the photosensitive polymer 30 that has penetrated to the bottom of the water from which the scarifying layer had been etched. This decreases the manufacture yield, and also can make it impossible to surely form the movable range of the detecting structure 13. This deteriorates the reliability of the sensor formed. Further, there is the need for etching the scarifying layer in two steps and then patterning the photosensitive polymer. This raises the manufacturing cost.

To solve the above-mentioned problem, Japanese Laid-Open Patent Publication No. 7-209105 and Japanese Laid-Open Patent Publication No. 7-245414 have also proposed inventions as shown in FIGS. 9(a)-(f). Referring to FIG. 9(a), an insulating layer 11 of BPSG or PSG is formed on the upper surface of an Si substrate 10, and a polysilicon 12 serving as movable and fixed electrodes is formed on the insulating layer 11. Here, an SOI wafer is formed by bonding together the Si substrate 10 and a wafer formed by an insulating layer 32 on the entire surface of an Si active layer 31 by way of oxide film, then grinding an unnecessary area and polishing, referring to FIG. 10, steps (a)-(e). Thereafter, a detecting structure 13 of a polysilicon or an active Si layer is formed by patterning and etching a resist, referring to FIG. 9(b). Referring to FIG. 9(c), the insulating layer 11 formed of BPSG, PSG, oxide film, or the like is etched as a scarifying layer by an etching solution 20, such as BHF.

Referring to FIG. 9(d), a sublimate 40, such as paradichrolobenzene or naphthalene, in a liquid form with a cleaning solution is applied. The sublimate 40 solidifies the gap between the detecting structure 13 and the Si substrate 10. The sublimate 40 is then sublimated to complete the detecting structure 13, referring to FIGS. 9(e) and 9(f).

In the above-described method, however, it is impossible to completely remove the sublimate 40. The remaining sublimate, i.e., undesirable foreign matter, remains on the surface of a cleaned sensor, thus deteriorating the reliability of the sensor.

Accordingly, there remains a need to surely prevent the sticking phenomenon in such a semiconductor, without necessitating any special process or leaving any foreign matter in the space from which the sacrificing layer has been removed or on the surface of a sensor. The present invention addresses this need.

### SUMMARY OF THE INVENTION

The present invention relates generally to a semiconductor device and a method of manufacturing the same, and more particularly to a semiconductor dynamic quantity sensor.

According to one aspect of the present invention, the semiconductor device has an SOI comprising a first layer formed of an Si substrate, a second layer formed of an oxide film, and a third layer formed of an Si. The second layer is positioned between the first and third layers. The third layer forms a detecting structure. At least one of opposing surfaces of the third layer and the first layer has an unevenness in height, which is formed by removing the second layer in contact with the detecting structure formed in the third layer as a sacrificing layer. Moreover, the first layer can be bonded to the third layer with the second layer formed between the first and third layer.

Micro-machining the surface of the structure thus can prevent the structure from sticking to a substrate at the bottom thereof in a process in which the bottom of the structure is etched as a scarifying layer and dried.

A high-concentration impurity region can be formed on all or a part of the surface on which the unevenness is formed. The unevenness has a height of 0.01 to 0.5 μm, and can be formed by subjecting to either one of a gas containing HF and an aqueous solution containing HF when the second layer is removed as the sacrificing layer. The high-concentration impurity region can be formed by implanting ions of 1×10¹⁴ atm/cm².

The semiconductor device can include an integral signal processing circuit. Moreover, the detecting structure can be a semiconductor strain gage type sensor or an electrical capacitance type sensor.

According to another aspect of the present invention, the method of manufacturing a semiconductor device comprises the steps of: forming a high-concentration impurity region on all or a part of a surface of at least one of an Si substrate forming a first layer and an Si forming a third layer, and bonding together the first layer and the third layer by way of an oxide film forming a second layer such that the high-concentration impurity region is sandwiched between the first layer and the third layer.

The method of manufacturing the semiconductor device can further include the steps of: forming a detecting structure in the third layer; and removing the second layer in contact with the third layer by either one of a gas containing HF or an aqueous solution containing HF, and forming an unevenness on a surface having the high-concentration impurity region at the same time.

The method of the semiconductor device further comprises the steps of: forming a passivation film after forming a signal processing circuit in the third layer; removing the passivation film on a region where the detecting structure is formed; patterning a resist for forming a detecting structure on the third layer from which the passivation film is removed, and forming the resist as a resist for protecting the passivation film; and forming a detecting structure in the third layer by dry etching or wet etching.

### BRIEF DESCRIPTION OF THE DRAWINGS

These and other features, aspects, and advantages of the present invention will become more apparent from the following description, appended claims, and accompanying exemplary embodiments shown in the drawings, which are briefly described below.

FIGS. 1(A)-1(C) are views showing an acceleration sensor that is an example of a semiconductor device manufactured according to the present invention, wherein FIG. 1 (A) is a top view showing the entire semiconductor device, FIG. 1 (B) is an enlarged view showing a sensor portion of the semiconductor device, and FIG. 1 (C) is a sectional view taken along line Y-Y of FIG. 1 (B).

FIG. 2 is a circuit diagram showing a Wheatstone bridge circuit comprised of semiconductor strain gages of the acceleration sensor of FIG. 1.

FIG. 3 illustrates a process of manufacturing an SOI wafer for manufacturing a semiconductor device according to the first embodiment of the present invention.

FIGS. 4(a)-4(f) are sectional views of the sensor portion formed during the process of manufacturing the semiconductor device according to the first embodiment of the present invention using the SOI wafer of FIGS. 3(a)-3(e), and FIGS. 4(g)-4(h) respectively are top and enlarged views of the semiconductor device.

FIG. 5 illustrates a process of manufacturing an SOI wafer for manufacturing a semiconductor device according to the second embodiment of the present invention.

FIGS. 6(a)-6(f) are sectional views of the sensor portion formed during the process of manufacturing the semiconductor device according to the second embodiment of the present invention using the SOI wafer of FIG. 5, and FIGS. 6(g)-6(h) respectively are top and enlarged views of the semiconductor device.

FIGS. 7(a)-7(e) are sectional views of the sensor portion formed during a conventional process of manufacturing a semiconductor device, and FIGS. 7(f)-7(g) respectively are top and enlarged views of the semiconductor device.

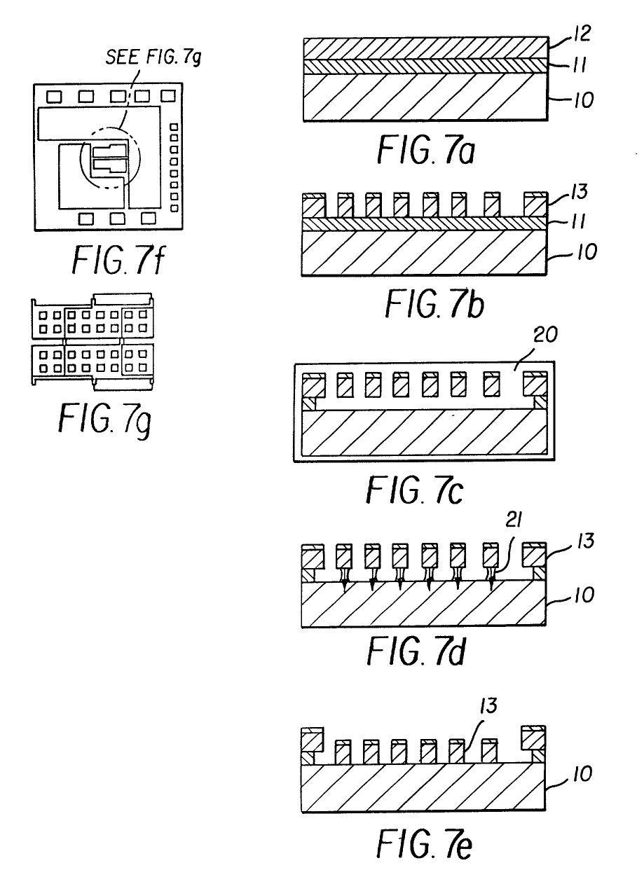

FIGS. 8(a)-8(h) are sectional and perspective views showing the improved conventional process of manufacturing the semiconductor device.

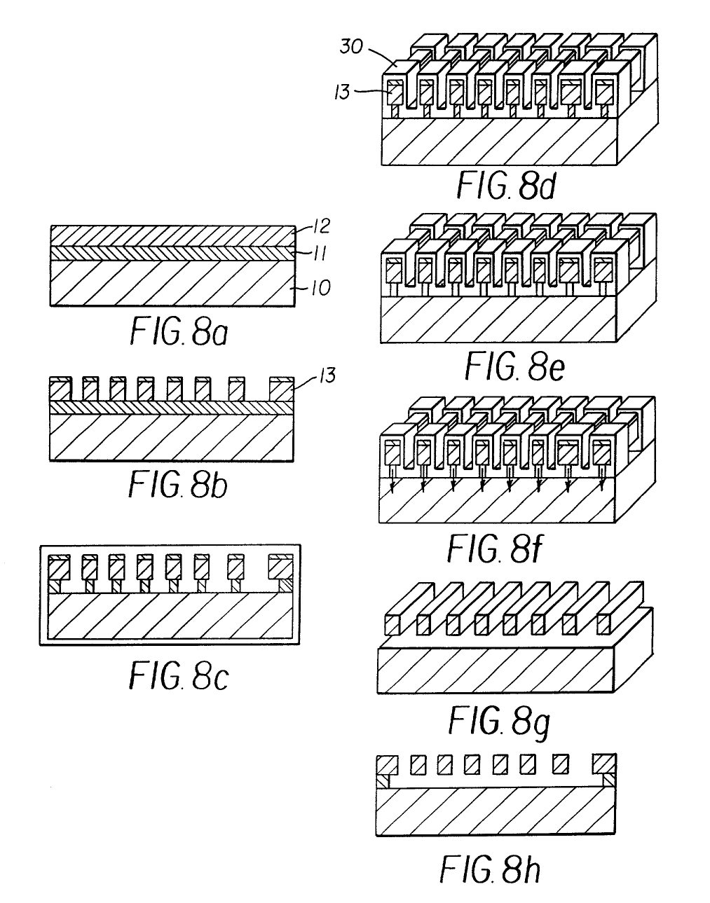

FIGS. 9(a)-9(f) are sectional views showing another improved conventional process of manufacturing the semiconductor device.

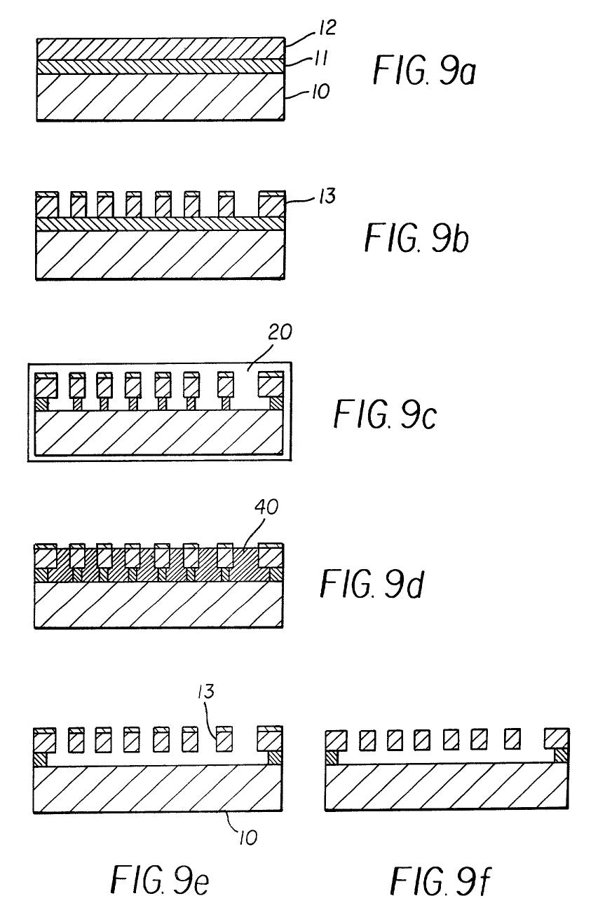

FIG. 10 illustrates a conventional process of manufacturing an SOI wafer for manufacturing a semiconductor device.

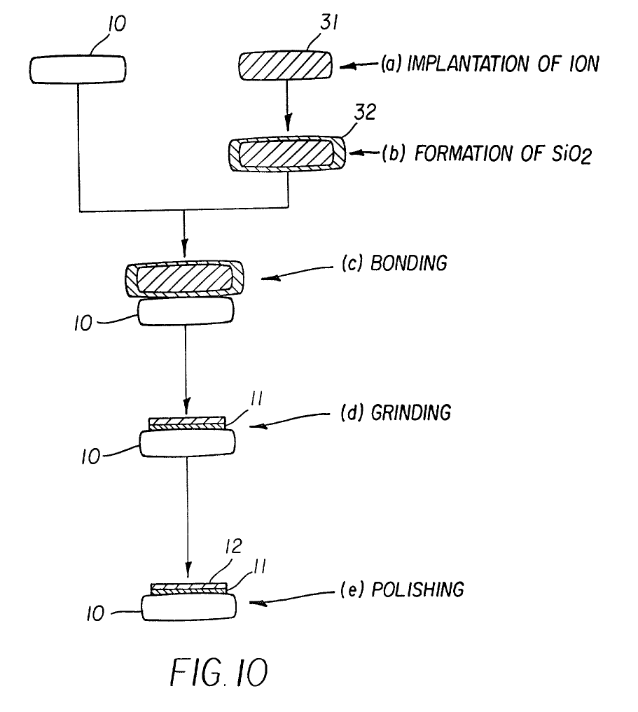

### DETAILED DESCRIPTION

Embodiments of the present invention will now be described in detail with reference to the accompanying drawings.

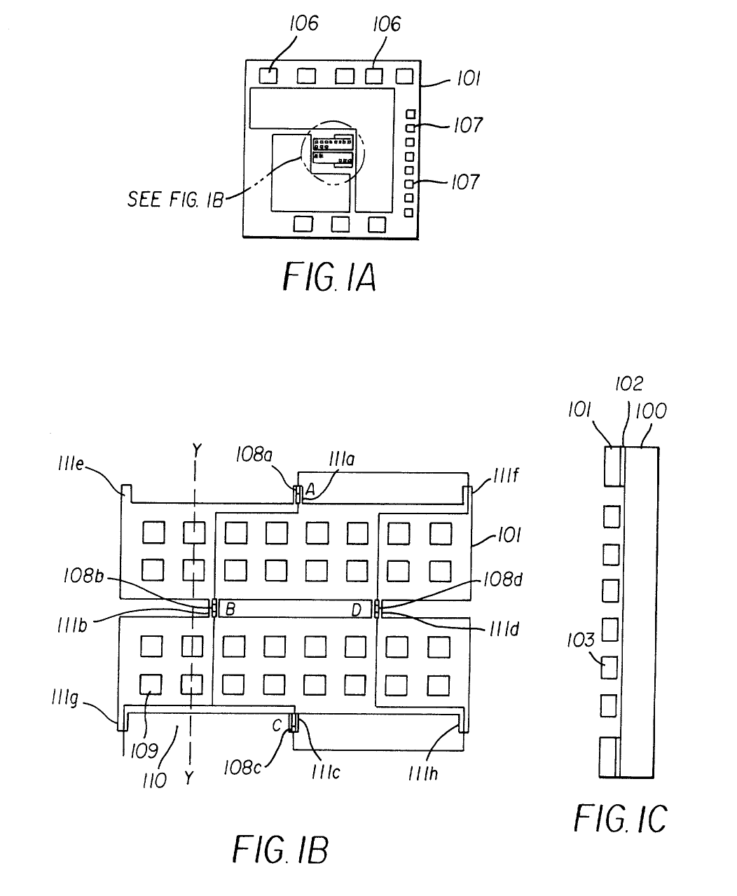

Referring to FIGS. 1(A)-1(C), which illustrate an acceleration sensor as an example of a semiconductor device that is manufactured according to the present invention, a semiconductor chip includes an SiO₂ layer 102, which serves as a second layer for an electrical isolating or a sacrificing layer formed between an Si substrate 100 of, for example, the N type forming the first layer and an Si layer 101 of, for example, the N type forming the third layer. The semiconductor chip also includes a detecting structure 103 integrated with a signal processing circuit (not illustrated) and an input/output terminal 106 formed on the Si substrate 100 forming the first layer. The Si substrate 100 forming the first layer and the Si layer 101 forming the third layer may also be of the P type. The Sio₂ layer or the second layer 102 is removed from the bottom of the detecting structure 103, which is arranged in the central section of the chip, so that the detecting structure 103 can freely move in the direction of the depth.

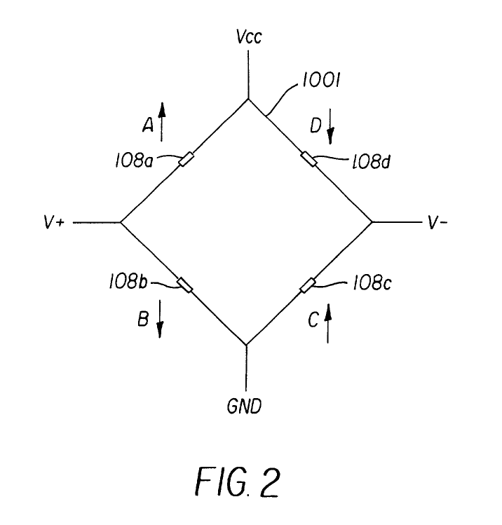

Referring to FIG. 1(B), the detecting structure 103 includes four beam portions 111a, 111b, 111c, 111d on which semiconductor strain gages 108a, 108b, 108c, 108d are formed respectively. The structure 103 also has wired beam portions 111e, 111f, 111g, 111h, and a weight portion in which sacrificing layer etching holes 109 are formed. These semiconductor strain gages 108a, 108b, 108c, 108d constitute a Wheatstone bridge circuit 1001, as illustrated in FIG. 2. That is, the signal processing circuit (not illustrated) amplifies an output voltage from the Wheatstone bridge circuit having the four semiconductor gages 108a, 108b, 108c, 108d.

If an acceleration is applied to the acceleration sensor constructed in the above-mentioned manner in a direction indicated by an arrow of FIG. 1 (C), a compressive stress is generated in the two semiconductor strain gages 108b, 108d among the four semiconductor gages 108a, 108b, 108c, 108d to reduce the resistivity thereof, whereas a tensile stress is generated in the other two semiconductor gages 108a, 108c to increase the resistivity thereof. Therefore, a sensor output corresponding to the acceleration is obtained from terminals V+ and V− of the Wheatstone bridge circuit 1001.

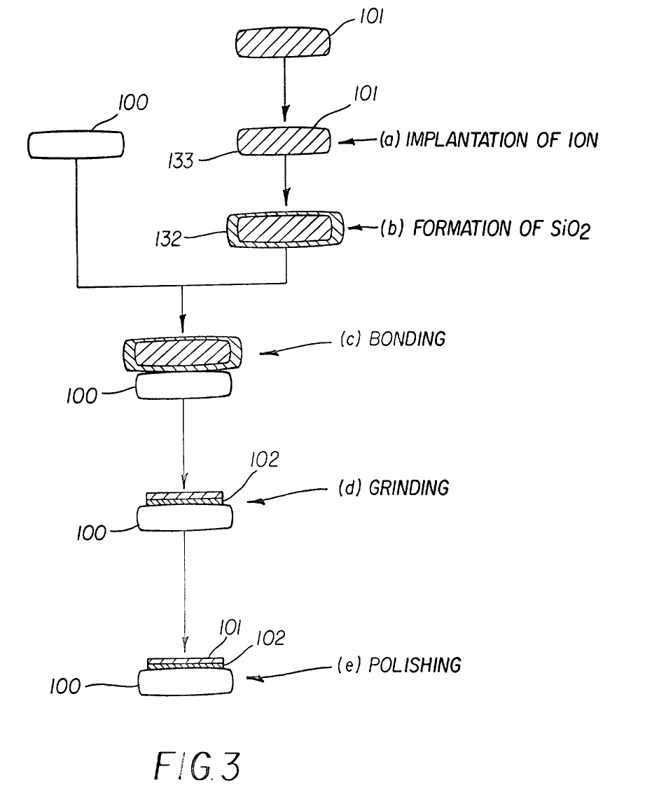

Referring to FIG. 3, a description will now be given of a process for manufacturing an SOI wafer, which process corresponds to the first half of the acceleration sensor manufacturing process shown in FIGS. 1(A)-1(C). At step (a), a high-concentration impurity region 133 is formed over the entire surface 133 of the Si layer 101, i.e., the third layer, formed over the Si substrate 100, i.e., the first layer. This high-concentration impurity region 133 is formed by implanting ions of 1×10¹⁴ atm/cm² or more (e.g., BF2, B11, and P). The implantation of 10¹⁵ atm/cm² or more would make etching easier and increase the height of the unevenness.

At step (b), the ion implanted Si layer 101 is thermally oxidized to form an SiO₂ layer, which can serve as the second layer 102. At step (c), a wafer formed of the Si substrate 100 forming the first layer and a wafer formed of the Si 101 forming the third layer are bonded together by applying a high pressure (e.g. 80×10⁴ to 20×10⁴ Pa (Pascal)) at a high temperature (e.g. 800 to 1000° C.). At step (d), the exposed SiO₂ layer is then ground to expose the third layer 101 having a predetermined thickness (e.g. 50 to 200 μm). At step (e), the third layer 101 is polished (mirror-polished) to a predetermined thickness (e.g. 5 to 10 μm) and a surface roughness of 0.001 μm or less, for example.

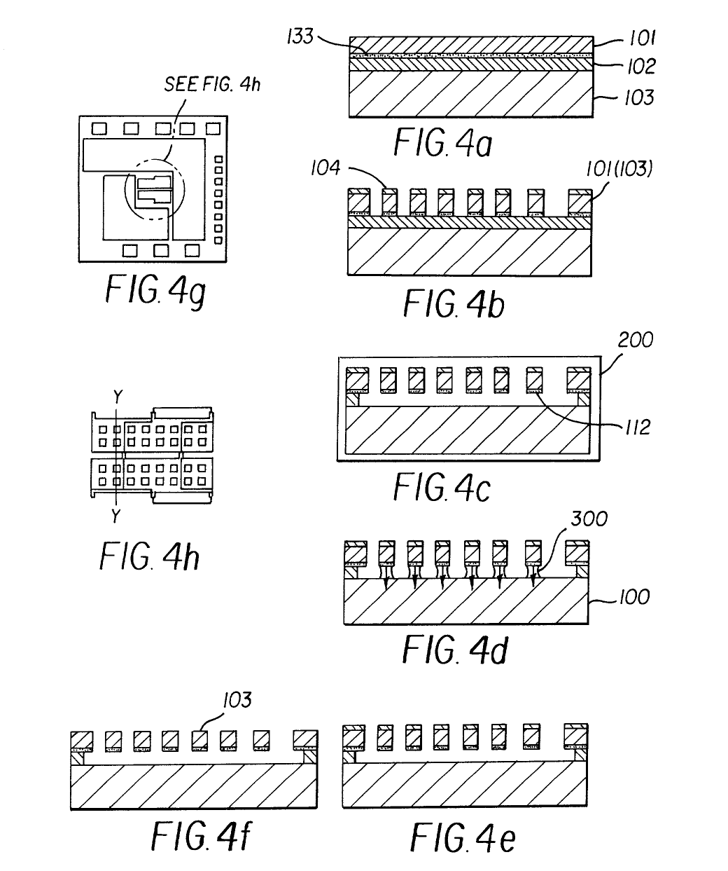

By using the SOI wafer thus manufactured, the acceleration sensor in FIG. 1 is manufactured according to the procedure shown in FIGS. 4(a)-4(f). It should be noted that FIGS. 4(a)-4(f) show the manufacturing process, but FIG. 4(b) is identical with FIGS. 1(A) and 1(B) and is only inserted to make it easier to understand the invention. A description will now be given of the procedure for manufacturing the acceleration sensor.

In FIG. 4(a), an IC device, a diffusing wire, an Al wire, an Al pad, etc. (not illustrated) constituting a signal processing circuit are formed in a region of the third layer 101, where the signal processing circuit is formed. The semiconductor strain gages 108 are also formed in this region. Thereafter, a passivation film (not illustrated) is formed. The passivation film is removed from a region (including the beam portions 111 in this case) of the Si 101 forming the detecting structure 103, where the detecting structure 103 is formed. A resist 104 for forming the detecting structure 103 is patterned on the third layer 101. The resist 104 on the region where the detecting structure 103 is formed is adhered to the third layer 101, and in the region where the signal processing circuit is formed. The resist 104 is adhered to the exposed passivation film to protect it.

In FIG. 4(b), grooves (110 in FIG. 1) and holes (109 in FIG. 1(B)) for specifying the contour or the pattern of the detecting structure 103 is formed in the third layer 101 by dry etching, wet etching, or the like. Beam portions (111 in FIG. 1(B)) are also formed. Thereafter, referring to FIG. 4(c), the oxide film (SiO₂ layer, i.e., sacrificing layer) 102 forming the second layer 102 is removed (sacrificing layer is etched) by a gas including HF, an aqueous solution 200 including HF or the like. At the same time, the surface of the third layer 101 is roughened by the gas or aqueous solution 200 containing HF due to a high surface impurity concentration (stain etching) since the high-concentration impurity region 133 is formed in the third layer 101 as described with reference to FIG. 3. Consequently, the third layer 101 has unevenness 112 of a depth of about 0.01 to 0.5 μm. This unevenness depends on the depth of the high-concentration impurity region 133. The high-concentration impurity region 133 and the Si 101 forming the third layer may be mixed in the surface of the unevenness. Namely, at the bottom of the portion 112, there are two portions. One portion is the portion (the exposed portion of the third layer) where the high impurity concentration impurity regions 133 is completely removed by etching and another portion is the rest where the impurity region 133 is not completely removed by etching. The term “mixed” refers to the fact that both portions may exist.

Referring to FIGS. 4(d) and 4(e), the gas containing HF or the aqueous solution 200 containing HF, substituted with pure water, IPA (isopropyl alcohol), etc., is applied to the device. The surface tension 300 of drying substituted liquid generates a tension to pull the detecting structure 103 formed in the third layer 101 toward the Si substrate 100 forming the first layer, the tension depending on the size of the contact area. The unevenness 112 on the surface of the third layer 101 reduces the contact area between the Si substrate 100 forming the first layer and the third layer 101. This prevents the sticking phenomenon during the drying phase. Referring to FIG. 4(f), after drying, the resist 104 is removed by ashing or the like to complete the detecting structure 103.

Although in this embodiment, an SiO₂ layer 132 is formed with the third layer 101, the SiO₂ layer can be similarly formed with the Si substrate Si 100 forming the first layer.

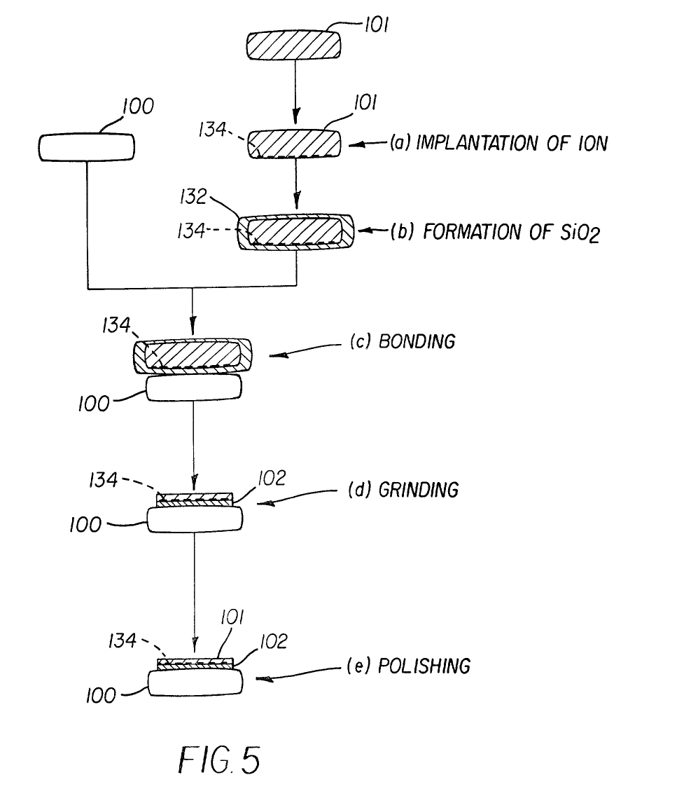

Referring to FIG. 5, illustrates another example of an SOI wafer manufacturing process according to the second embodiment of the present invention. In step (a), a resist is patterned on a part, e.g. a circular area with a pitch of 30 to 50 μM and 5 to 10 μm on the surface of the Si layer 101 (third layer), which is opposed to the Si substrate 100 forming the first layer, and ions of 1×10⁴ atm/cm² or more are implanted into the entire surface of the wafer except for the patterned area. Reference numeral 134 denotes a high-concentration impurity region where the ions are implanted. In step (b), by thermally oxidizing the third layer 101, a SiO₂ layer, which can serve as the second layer 102 is formed on the third layer. In step (c), a wafer formed of the Si substrate 100 forming the first layer and a wafer 101 (third layer) are bonded together by applying a high pressure (e.g. 80×10⁴ to 20×10hu 4 Pa) at a high temperature (e.g. 800 to 1000° C.).

In step (d), the exposed SiO₂ layer and the third layer are then ground to form the third layer 101 having a predetermined thickness (e.g. 50 to 200 μm). Thereafter, in step (e), the exposed third layer is then polished to a predetermined thickness (e.g. 5 to 100 μm).

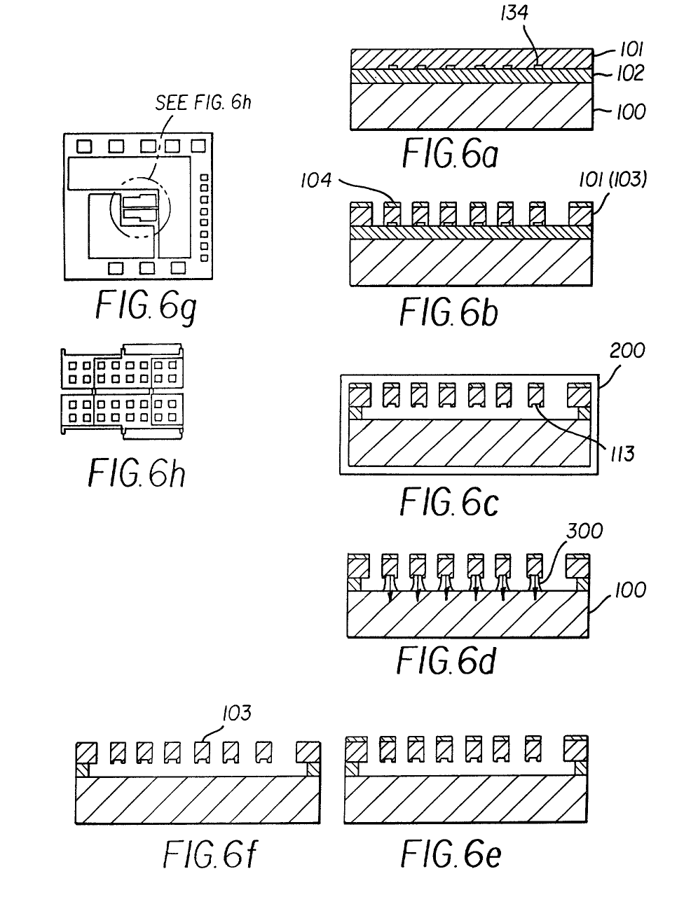

By using the SOI wafer thus manufactured, the acceleration sensor in FIGS. 1(A)-1(C) is manufactured according to the procedure shown in FIGS. 6(a)-6(f). It should be noted that FIGS. 6(a)-6(f) show the manufacturing process, but FIG. 6(g) is identical with FIGS. 1(A) and 1(B) and is only inserted to make it easier to understand the invention. A description will now be given of the procedure for manufacturing the acceleration sensor.

In FIG. 6(a), an IC device, a diffusing wire, an Al wire, an Al pad, etc. (not illustrated) constituting a signal processing circuit are formed in a region of the third layer where the signal processing circuit is formed. A passivation film (not illustrated) is formed over this region. The passivation film is removed from a region (including the beam portion 111 in this case) of the Si 101 forming the third layer where the detecting structure 103 is formed. A resist 104 for forming the detecting structure 103 is patterned on the third layer 101. The resist 104 on the region where the detecting structure 103 is formed is adhered to the third layer 101, and in the region where the signal processing circuit is formed, the resist 104 is adhered to the exposed passivation film to protect it.

In FIG. 6(b), grooves and holes for specifying the contour of the detecting structure 103 or its pattern is formed in the third layer 101 by dry etching, wet etching, or the like. Beam portions 111 are also formed. Thereafter, referring to FIG. 6(c), the oxide film SiO₂ layer (i.e., sacrificing layer) 102 forming the second layer is removed (scarifying layer is etched) by a gas including HF, an aqueous solution 200 including HF, or the like. At the same time, a resist is patterned on a circular area with a pitch of 30 to 50 μm and 5 to 10 μm on the third layer 101, and the ions of 1×10¹⁴ atm/cm² or more are implanted into the entire surface of the wafer except for the patterned area as described with reference to FIG. 5. Thus, the surface of the Si forming the third layer 101 is roughened by the gas or the aqueous solution 200 containing HF due to a high surface impurity concentration (stain etching) in a high-concentration impurity region 134 where the ions are implanted. The high concentration impurity region 134 where the ions are implanted is circular shaped and etched to form the unevenness 113 with a depth of about 0.01 to 0.5 μm in the Si surface forming the third layer 101. This unevenness depends on the depth of the high-concentration impurity region 134. The high-concentration impurity region 134 and the Si surface forming the third layer 101 may be mixed in the surface of the unevenness. Namely, at the bottom of the portion 113, there are two portions. One portion is the portion (the exposed portion of the third layer) where the high impurity concentration impurity regions 134 is completely removed by etching and another portion is the rest where the impurity region 134 is not completely removed by etching. The term “mixed” refers to the fact that both portions may exist.

Referring to FIGS. 6(d) and 6(e), the gas containing HF or the aqueous solution 200 containing HF, substituted with pure water, IPA (isopropyl alcohol), etc., is applied to the device. The surface tension 300 of drying substituted liquid generates a tension to pull the detecting structure 103 formed in the third layer 101 toward the Si substrate 100 forming the first layer, the tension depending on the size of the contact area. The unevenness in height 1 13 on the surface of the third layer reduces the area contacting the Si substrate 100 forming the first layer. This prevents the sticking phenomenon during the drying phase. Referring to FIG. 6(f), after drying, the resist is removed by ashing or the like to complete the detecting structure 103.

Although in the above described first and second embodiments, the high-concentration impurity region is formed on all or a part of the surface of the Si forming the third layer 101 opposed to the Si substrate 100 forming the first layer, it is not to be limited thereto, as the high-concentration impurity region can be formed on all or a part of the surface of the Si substrate forming the first layer opposed to the Si forming the third layer.

Further, the high-concentration impurity region can be formed on the respective surfaces of the Si substrate forming the first layer and the Si layer forming the third layer opposed to the Si substrate.

Further, although in the first and second embodiments, the present invention is applied to the semiconductor strain gage type sensor, it is not to be limited thereto, as the present invention also can be applied to an electrical capacitance type sensor using an SOI wafer, for example.

According to the present invention, the height unevenness is formed on at least one of the opposing surfaces of the first and third layers. This height unevenness reduces the contact area between the third and first layers to reduce the adhering power of the third layer toward the first layer, which is generated by the surface tension of the liquid to thus surely prevent the sticking phenomenon that has been the most serious problem during the etching of the scarifying layer. This enables the manufacture of a reliable semiconductor device with a high yield.

Further, according to the present invention, it is not necessity to carry out a complicated process for prevention of the sticking phenomenon, which can reduce the cost of manufacturing a semiconductor device, such as a semiconductor sensor.

Given the disclosure of the present invention, one versed in the art would appreciate that there may be other embodiments and modifications within the scope and spirit of the present invention. Accordingly, all modifications attainable by one versed in the art from the present disclosure within the scope and spirit of the present invention are to be included as further embodiments of the present invention. The scope of the present invention accordingly is to be defined as set forth in the appended claims.

The disclosure of the priority application, JP PA 2001-048654, in their entirety, including the drawings, claims, and the specification thereof, is incorporated herein by reference.

We claim:

1. A semiconductor device comprising:
an SOI comprising a first layer formed of an Si substrate, a second layer formed of an oxide film, and a third layer formed of an Si,
wherein the second layer is positioned between the first and third layers,
wherein the third layer forms a detecting structure,
wherein at least one of opposing surfaces of the third layer and the first layer has an unevenness, and.
wherein second layer in contact with the detecting structure formed in the third layer is removed as a sacrificing layer to form the unevenness.

2. A semiconductor device according to claim 1, wherein the first layer is bonded to the third layer with the second layer formed between the first and third layer.

3. A semiconductor device according to claim 1, wherein a high-concentration impurity region is formed on all or a part of the surface on which the unevenness is formed.

4. A semiconductor device according to claim 1, wherein the unevenness has a depth of 0.01 to 0.5 μm.

5. A semiconductor device according to claim 1, wherein the unevenness is formed by subjecting to either one of a gas containing HF and an aqueous solution containing HF when the second layer is removed as the sacrificing layer.

6. A semiconductor device according to claim 3, wherein the high-concentration impurity region is formed by implanting ions of 1×10 ¹⁴ atm/cm².

7. A semiconductor device according to claim 1, further including a signal processing circuit integrated with the semiconductor device.

8. A semiconductor device according to claim 1, wherein the detecting structure is a semiconductor strain gage type sensor or an electrical capacitance type sensor.

9. A method of manufacturing a semiconductor device, comprising the steps of:
forming a high-concentration impurity region on all or a part of a surface of at least one of an Si substrate forming a first layer and an Si forming a third layer; and
bonding together the first layer and the third layer by way of an oxide film forming a second layer such that the high-concentration impurity region is sandwiched between the first layer and the third layer.

10. A method of manufacturing a semiconductor device, according to claim 9, further comprising the steps of:
forming a detecting structure in the third layer; and
removing the second layer in contact with the third layer by either one of a gas containing HF or an aqueous solution containing HF, to form an unevenness on the surface having the high-concentration impurity region.

11. A method of manufacturing a semiconductor device according to claim 10, further comprising the steps of:
forming a passivation film after forming a signal processing circuit in the third layer;
removing the passivation film on a region where the detecting structure is formed;
patterning a resist for forming a detecting structure on the third layer from which the passivation film is removed, and forming the resist for protecting the passivation film; and
forming a detecting structure in the third layer by dry etching or wet etching.
